(19) United States
(12) Patent Application Publication
(10) Pub. No.: US 2014/0073133 A1
(43) Pub. Date: Mar. 13, 2014

(54) METHOD TO MITIGATE THROUGH-SILICON VIA-INDUCED SUBSTRATE NOISE

(71) Applicants: Nauman H. Kahn, Beaverton, OR (US); Soha Hassoun, Lexington, MA (US); Syed M. Alam, Austin, TX (US)

(72) Inventors: Nauman H. Kahn, Beaverton, OR (US); Soha Hassoun, Lexington, MA (US); Syed M. Alam, Austin, TX (US)

(73) Assignee: Tufts University, Medford, MA (US)

(21) Appl. No.: 14/004,472

(22) PCT Filed: Mar. 14, 2012
(86) PCT No.: PCT/US12/29003

§ 371 Date: Nov. 20, 2013

Related U.S. Application Data
(60) Provisional application No. 61/452,238, filed on Mar. 14, 2011.

(51) Int. Cl. H01L 21/768

(52) U.S. Cl. CPC H01L 21/768
USPC 438/667

(57) ABSTRACT

A semiconductor manufacture includes a first semiconductor including a substrate die having a first surface and having a second surface upon which integrated circuitry is disposed; a second semiconductor die; a through-silicon via (TSV) extending through the first semiconductor die and electrically connected to the second semiconductor die; and at least one ground plug including an electrically conductive material, positioned proximally to the TSV and extending into the substrate of the first semiconductor die from one of the first surface or the second surface.

### CROSS-REFERENCE TO RELATED APPLICATIONS

This application claims the benefit of U.S. Provisional Application No. 61/452,238, filed Mar. 14, 2011, incorporated herein by reference.

### BACKGROUND

3D packages and 3D integrated circuits generally contain two or more chips (integrated circuits) stacked vertically so that they occupy less space than an integrated circuit having one layer. The use of through-silicon vias (TSVs) has become an important technology in creating 3D packages and 3D integrated circuits. TSVs are generally characterized by a vertical electrical connection (via) passing completely through a silicon wafer or die and serves as an interconnect element between connection points devices within a die or on stacked dies. However, TSVs are a major source of substrate noise resulting in performance degradation of neighboring active devices. The signals passing through the TSVs can generate noise that propagates within the substrate of a die impacting the performance of neighboring active devices or neighboring TSVs. For example, TSV-induced noise increases leakage current, which increases power consumption and can erroneously switch transistors off or on.

### SUMMARY

The invention relates generally to a grounding structure. The grounding structure serves as an electrical grounding of the substrate of a semiconductor die. When applied in the context of TSV noise mitigation, the structure extends into the substrate alongside the TSV. In a general aspect, a semiconductor manufacture comprises a first semiconductor die including a substrate having a first surface and having a second surface upon which integrated circuitry is disposed; a second semiconductor die; a through-silicon via (TSV) extending through the first semiconductor die and electrically connected to the second semiconductor die; and at least one ground plug including an electrically conductive material, positioned proximally to the TSV and extending into the substrate of the first semiconductor die from one of the first surface or the second surface.

In another general aspect, a method relates to mitigating substrate noise in a semiconductor manufacture including a first semiconductor die and a second semiconductor die. The first semiconductor die includes a substrate that has a first surface and that has a second surface upon which integrated circuitry is disposed. The semiconductor manufacture also includes a through-silicon via (TSV) extending through the first semiconductor die and electrically connected to the second semiconductor die. The method comprises providing at least one ground plug including an electrically conductive material, electrically positioned proximally to the TSV and extending into the substrate of the first semiconductor die from one of the first surface or the second surface.

Embodiments of these aspects may include one or more of the following features.

The ground plug includes tungsten and can have a circular cross-section, for example, having a diameter that is in arrange between 10-50% of the diameter of the TSV. In one implementation, the GND plug has a diameter that is about 25% of the diameter of the associated TSV.

In some embodiments, the ground plug extends partially through the substrate of the first semiconductor die, while in other embodiments, the ground plug extends from the first surface to the second surface of the substrate of the first semiconductor die.

The semiconductor manufacture may include a plurality of ground plugs associated with the TSV, and in some implementations each ground plug is spaced substantially the same distance from the TSV.

In some implementations, the ground plug may be electrically connected to the integrated circuitry disposed on the second surface of the substrate of the first semiconductor die, for example, via a local interconnection. Alternatively, the ground plug is electrically connected to circuitry (e.g., a ground network) on the second semiconductor die, for example, via a global interconnection

Among other advantages, the semiconductor manufactures and methods described herein provide a practical and relatively simpler approach to mitigating TSV-induced substrate noise. Use of a ground (GND) plug provides effective noise isolation with a much smaller real estate (area on the semiconductor die) penalty when compared to other approaches for mitigating TSV-induced substrate noise. The use of backside GND plugs can also further reduce the area penalty in some circuits. The magnitude of the noise mitigation provided by GND plugs is also potentially larger than other approaches (e.g., by an order of magnitude in some arrangements). The use of one or more GND plugs can be applied to mitigate noise from other sources such as a latchup or other parasitic structures. Additionally, GND plugs can be combined with other approaches for noise mitigation, as described in more detail below.

### BRIEF DESCRIPTION OF DRAWINGS

FIG. 1 is a cross-sectional view of a three-dimensional integrated circuit (3-D IC) including through-silicon via (TSV) and associated ground (GND) plugs.

FIG. 2 is a top view of a representative one of the TSVs and associated ground plugs.

FIG. 3 is a top view of showing labeled dimensions of a TSV and associated ground plugs.

FIGS. 4a-4c are plots of peak transient noise for different respective configurations of ground plugs.

### DETAILED DESCRIPTION

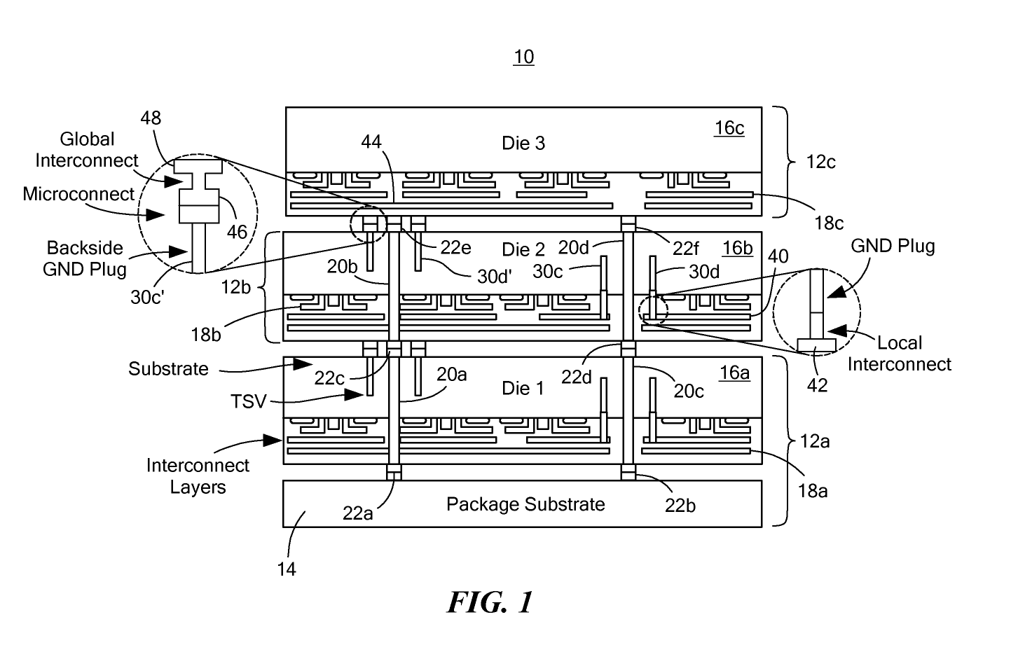

Referring to FIG. 1, a three-dimensional integrated circuit (3-D IC) 10 includes three semiconductor dies 12a, 12b, 12c stacked vertically over a package substrate 14. Each semiconductor die 12a, 12b, 12c includes a substrate 16a, 16b, 16c (e.g., a silicon substrate, or a silicon on insulator (SOI) substrate) having active integrated circuitry 18a, 18b, 18c. Integrated circuitry 18a, 18b, 18c includes semiconductor devices (e.g., MOSFET transistors) fabricated on a surface of the respective substrate 16a, 16b, 16c, and passive components such as interconnect layers comprising networks of conducting paths for interconnecting the semiconductor devices. Through-silicon vias (TSVs) 20a-20d serve to interconnect dies 12a, 12b, 12c.

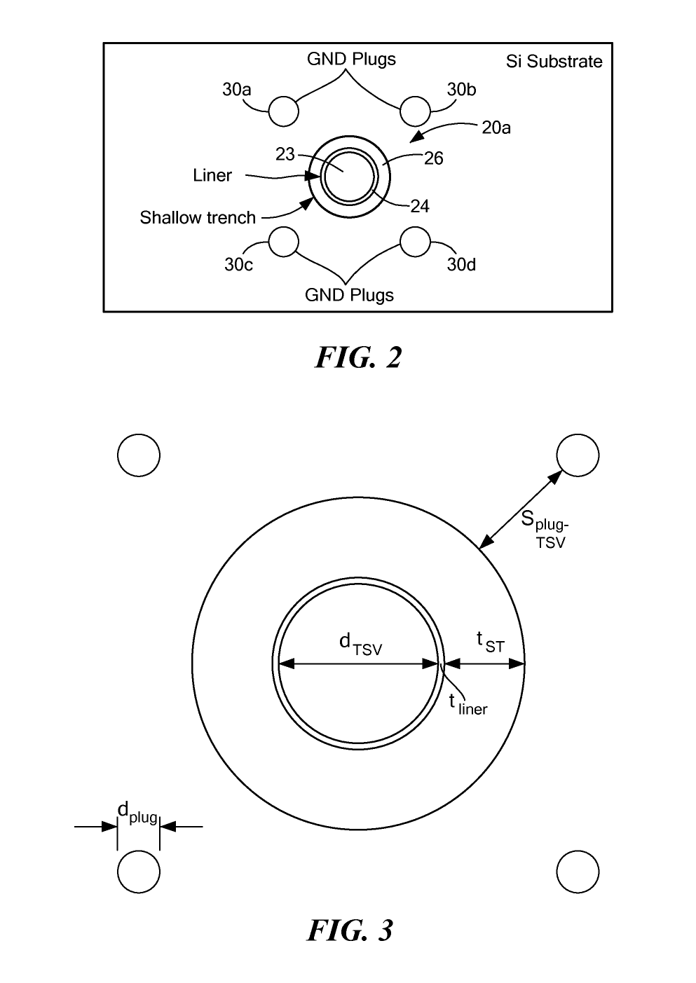

Referring to FIG. 2, each TSV includes a conducting core 23 formed of a conductive material (e.g., copper), and is surrounded by a liner 24 formed of a dielectric material, and a shallow trench 26 around the liner 24 in the surface of the substrate. In this embodiment, four ground (GND) plugs 30a-30d surround TSV 20a. As will be described in greater detail below, each set of GND plugs associated with a TSV are connected to a circuit ground and serve to provide noise isolation between a TSV and neighboring devices in the integrated circuitry. In some cases, GND plugs 30a-30d that extend more deeply into the substrate or extend entirely through the substrate are generally preferable. Similarly, decreasing the spacing from its associated TSV tends to increase noise isolation. However, the depth of each GND plug and proximal spacing can be limited by neighboring circuitry and manufacturing techniques.

Referring again to FIG. 1, in this embodiment, a first pair of TSVs 20a, 20b extending through semiconductor dies 12a, 12b, respectively; and a second pair of TSVs 20c, 20d extending through semiconductor dies 12a, 12b, respectively. TSVs 20a, 20c have lower ends connected to package 14 through microconnects 22a, 22b and upper ends connected to lower ends of TSVs 20b, 20d through microconnects 22c, 22d, respectively. TSVs 20b, 20d extend through semiconductor die 12b and have upper ends connected to semiconductor die 12c through microconnects 22e, 22f.

One example of a set of GND plugs 30a-30d distributed proximally to TSV 20d (only two of which are shown in FIG. 1) are connected to a ground network layer 40 within integrated circuitry 18b through a local interconnect 42. In this example, the GND plugs reside entirely within semiconductor die 12b.

In another example, a second set of GND plugs 30a′-30d′ distributed proximally to TSV 20b (only two of which are shown in FIG. 1) extend within semiconductor die 12b but are connected to a ground network layer 44 disposed within neighboring semiconductor die 12c. For example, GND plug 30c′ is connected to the ground network 44 through a microconnect 46 and global interconnect 48. In this example, GND plugs 30a′-30d′ are referred to backside GND plugs since they extend into the substrate 16b from the back side of the substrate 16b (the side opposite to the side on which the integrated circuitry 18b is fabricated). In some cases, GND plugs 30a′-30d′ that extend more deeply into the substrate are generally preferable. However, in some cases, a backside GND plug is configured to extend only partially through the substrate (e.g., 80% or 90% of the thickness of the substrate) so that the end of the GND plug does not interfere with the integrated circuitry 18b disposed on the opposite side of the substrate.

In some embodiments, the back side also includes a backside ground plane comprising a conducting layer (e.g., formed as a plate or a grid) covering a relatively large portion of the surface of the substrate 16b and electrically connected to a circuit ground. For example, a layer of metal that is 2 μm thick can be applied to the back side of a substrate that is 20 μm thick. The backside ground plane may also provide some noise mitigation, but not as much as the GND plugs in some cases (e.g., depending on how thick the substrate 16b is). In some embodiments, backside GND plugs are used without a backside ground plane since the ground planes of different dice may introduce inductive coupling.

If the GND plug resides within a semiconductor die, via technology can be used to make the GND plug. If the GND plug is a backside GND plug, the GND plug can be fabricated by backside lithography as part of a via-last process. The GND plugs can be fabricated with a conductive metal such as tungsten or copper. Tungsten is particularly advantageous because it has a smaller coefficient of thermal expansion mismatch when used with silicon (e.g., compared to copper), resulting in less thermal stress in devices. In some embodiments, tungsten is used without a diffusion barrier that would be used with other metals, which provides a direct connection between the substrate and a circuit ground, potentially resulting in better device shielding. In some embodiments, while a metal other than tungsten may be used for the conducting core of the TSVs (e.g., a metal such as copper having a lower resistivity than tungsten), tungsten may still be used for the GND plugs since tungsten may provide higher RC damping for less noise transfer from a power supply.

GND plugs can be combined with other approaches for noise mitigation. For example, a keep out zone around each TSV can be specified (e.g., through layout rules that provide a minimum TSV-to-device distance) to shield devices from neighboring TSVs, and GND plugs can be used to further reduce noise, and/or to decrease the size of keep out zones and provide more usable space for circuitry. Other approaches include using one or more of: a thicker TSV liner, a backside ground plane, a guard ring structure, and co-axial TSVs. A backside ground plane is generally more effective for thinner substrates.

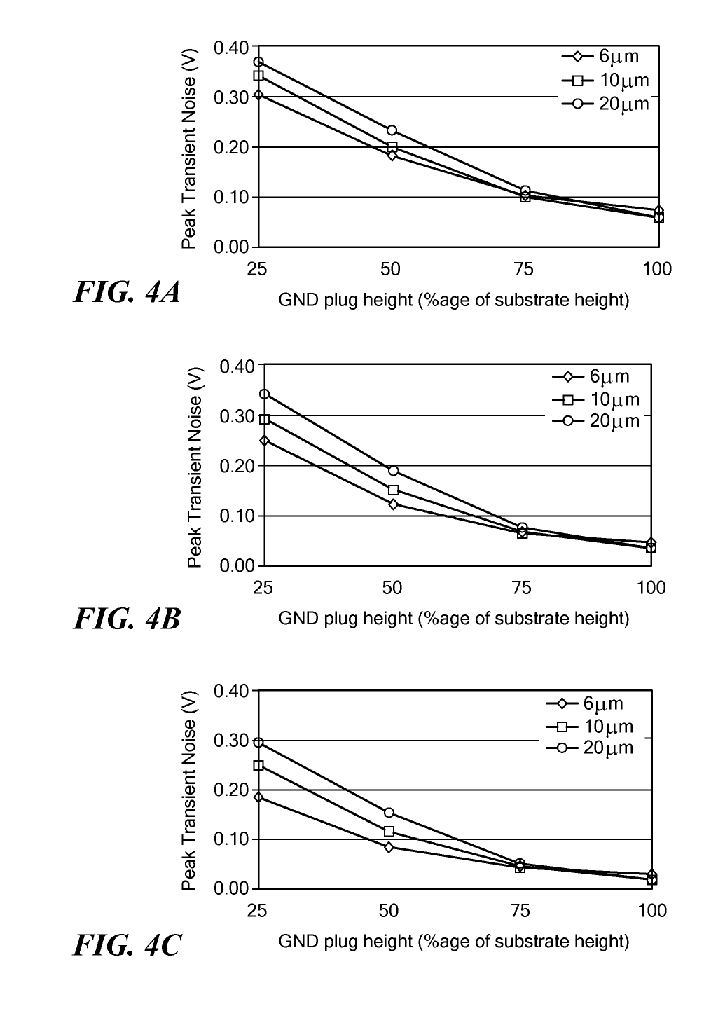

Examples of particular configurations of GND plugs are specified below, with results from simulations of noise characteristics for those configurations shown in FIGS. 4a-4c for different sizes of GND plugs. In these examples, the substrate and the TSVs are assumed to have the following characteristics, with distances in the cross-sectional plane shown in FIG. 3 (not to scale). The substrate has a thickness of 20 μm, and is composed of a material with a volume resistivity of 10 Ω-cm and a relative permittivity of 11.8. This type of substrate is typically used, for example, to fabricate low cost, low performance devices such as memory. The conducting cores of the TSVs have a cylindrical shape with a cross-sectional diameter d_{TSV} of 2 μm, and are composed of copper. The dielectric liners surrounding the cores have a thickness tₗᵢₙₑᵣ of 0.1 μm, and are composed of silicon dioxide, with a volume resistivity of 1016 Ω-cm and relative permittivity of 3.9. The shallow trench around the liner has a thickness t_{ST} of 0.9 μm and a depth (into the surface of the substrate) of 0.3 μm. The distance S_{plug-TSV} between the edge of the shallow trench and the edge of the GND plugs is 3 μm.

FIGS. 4a-4c show plots of the peak transient noise for three different values of the GND plug diameter d_{plug} (FIG. 3). FIG. 4a assumes a value for d_{plug} of 0.5 μm (25% of the diameter d_{TSV} of the core of the TSV). FIG. 4b assumes a value for d_{plug} of 1.0 μm (50% of the diameter d_{TSV} of the core of the TSV). FIG. 4c assumes a value for d_{plug} of 1.5 μm (75% of the diameter d_{TSV} of the core of the TSV). Each figure includes three different plots, each plot showing peak transient noise (measured in Volts) for a particular observation distance from the center of the TSV: 6 μm (for the bottom plots with diamond-shaped plot points); 10 μm (for the middle plots with square-shaped plot points); and 20 μm (for the top plots with circle-shaped plot points). Each plot includes plot points for four different values of the GND plug depth into the substrate relative to the full depth of the substrate: 25%, 50%, 75%, and 100%. The peak transient noise is calculated based on a model simulating the TSV and GND plug configurations as RLC circuits (in SPICE).

Based on these simulation results, a deeper GND plug is more effective than a shallower one in reducing peak noise, and a larger GND plug diameter is more effective than a smaller diameter. However, if the GND plug is on the circuit side of the substrate, the benefit of larger GND plug diameter occurs at the expense of a larger area that is unavailable for circuitry, with diminishing benefit in noise reduction. For a factor of 3 increase in GND plug diameter from 0.5 μm to 1.5 μm, there is about 10% more noise reduction. The tradeoff between noise mitigation and usable area in selecting GND plug diameter may be relative to the diameter of the TSV. In some embodiments, a GND plug diameter is selected that is in a range between about 10-50% of the diameter of the TSV. For the example in which the diameter d_{TSV} of the core of the TSV is 2 μm, a GND plug diameter of about 0.5 μm (25%) may be selected, for example.

Limitations of the fabrication process may also affect the GND plug configurations that can be achieved. For example, for some fabrication systems, GND plug diameter and depth are related due to aspect ratio limitations of deep core formation and filling in a silicon substrate. For deep GND plugs with a relatively small diameter, aspect ratios (in depth-to-diameter) of around 40:1 may be desired. In some systems, smaller aspect ratios (e.g., around 20:1) may provide acceptable noise mitigation. Some systems are only able to maintain a uniform diameter when forming the hole (to be filled with the core material) for part of the depth into the substrate (e.g., around 70% of the depth). Since GND plugs do not necessarily require sidewall isolation or high uniformity of the diameter as a function of depth, some GND plugs can have shapes other than cylindrical. For example, a cone-shaped GND plug can be formed, with the base of cone on the surface of the substrate and the point of the cone directed into the surface.

Other characteristics, in addition to peak transient noise, may be relevant in some cases. For example, reduction in area penalty and routing blockages in comparison to other techniques may motivate the use of GND plugs even if the noise mitigation is not much better or even slightly worse than other techniques.

It is to be understood that the foregoing description is intended to illustrate and not to limit the scope of the invention, which is defined by the scope of the appended claims. For example, although in the description above, four GND plugs were used with each TSV, more or fewer GND plugs can be used depending on the real estate available and noise isolation characteristics required. Other embodiments are within the scope of the following claims.

1. The semiconductor manufacture of claim 24, wherein the at least one ground plug comprises:
at least two ground plugs including an electrically conductive material, at least a first ground plug positioned proximally to the TSV and extending into the substrate of the first semiconductor die from one of the first surface or the second surface, and at least a second ground plug extending into the substrate of the first semiconductor die from the first surface and electrically connected to a ground network on the second semiconductor die.

2. The semiconductor manufacture of claim 24, wherein the ground plug is formed of tungsten.

3. The semiconductor manufacture of claim 24, wherein the ground plug has a circular cross-section.

4. The semiconductor manufacture of claim 24, wherein the ground plug has a diameter that is in a range between 10% -50% of the diameter of the TSV.

5. The semiconductor manufacture of claim 24, wherein the ground plug extends partially through the substrate of the first semiconductor die.

6. The semiconductor manufacture of claim 1, wherein the first ground plug extends from the first surface to the second surface of the substrate of the first semiconductor die.

7. The semiconductor manufacture of claim 1, comprising a plurality of ground plugs associated with the TSV including the first ground plug, each of the plurality of ground plugs associated with the TSV spaced substantially the same distance from the TSV.

8. The semiconductor manufacture of claim 1, wherein the first ground plug is electrically connected to the integrated circuitry disposed on the second surface of the substrate of the first semiconductor die.

9. The semiconductor manufacture of claim 8 wherein the first ground plug is electrically connected to the integrated circuitry via a local interconnection.

10. (canceled)

11. (canceled)

12. The semiconductor manufacture of claim 24 wherein the ground plug is electrically connected to the ground network via a global interconnection.

13. The method of claim 25, wherein providing at least one ground plug comprises:
providing at least two ground plugs including an electrically conductive material, at least a first ground plug positioned proximally to the TSV and extending into the substrate of the first semiconductor die from one of the first surface or the second surface, and at least a second ground plug extending into the substrate of the first semiconductor die from the first surface and electrically connected to a ground network on the second semiconductor die.

14. The method of claim 25, comprising forming the ground plug from tungsten.

15. The method of claim 25, comprising forming the ground plug with a circular cross-section.

16. The method of claim 25, comprising forming the ground plug with a diameter that is in arrange a range between 10% and 50% of the diameter of the TSV.

17. The method of claim 25, comprising providing the ground plug partially through the substrate of the first semiconductor die.

18. The method of claim 13, comprising providing the first ground plug from the first surface to the second surface of the substrate of the first semiconductor die.

19. The method of claim 13, comprising electrically connecting the first ground plug to the integrated circuitry via a local interconnection.

20. (canceled)

21. The method of claim 25, comprising electrically connecting the ground plug to the ground network via a global interconnection.

22. The semiconductor manufacture of claim 5, wherein the ground plug extends at least 80% through the substrate of the first semiconductor die and ends far enough from the second surface of the substrate of the first semiconductor die to not interfere with integrated circuitry that is on the second surface opposite to the ground plug.

23. The method of claim 17, wherein the ground plug extends at least 80% through the substrate of the first semiconductor die and ends far enough from the second surface of the substrate of the first semiconductor die to not interfere with integrated circuitry that is on the second surface opposite to the ground plug.

24. A semiconductor manufacture comprising:
a first semiconductor die including a substrate having a first surface and having a second surface upon which integrated circuitry is disposed;
a second semiconductor die;
a through-silicon via (TSV) extending through the first semiconductor die and electrically connected to the second semiconductor die; and
at least one ground plug including an electrically conductive material, extending into the substrate of the first semiconductor die from the first surface and electrically connected to a ground network on the second semiconductor die.

25. A method for mitigating substrate noise in a semiconductor manufacture including a first semiconductor die and a second semiconductor die, the first semiconductor die including a substrate having a first surface and having a second surface upon which integrated circuitry is disposed, and a through-silicon via (TSV) extending through the first semiconductor die and electrically connected to the second semiconductor die, the method comprising:
providing at least one ground plug including an electrically conductive material, extending into the substrate of the first semiconductor die from the first surface and electrically connected to a ground network on the second semiconductor die.

26. The semiconductor manufacture of claim 24, wherein the ground plug is electrically connected to the ground network through a microconnect.

27. The method of claim 25, comprising electrically connecting the ground plug to the ground network through a microconnect.
